(19) United States
(12) Patent Application Publication
(10) Pub. No.: US 2013/0094155 A1
(43) Pub. Date: Apr. 18, 2013

(54) ELECTRONIC DEVICE AND ELECTRONIC DEVICE ASSEMBLY THEREOF

(71) Applicant: LINTES TECHNOLOGY CO., LTD, New Taipei (TW)

(72) Inventor: Wei-Zen Lo, New Taipei (TW)

(73) Assignee: LINTES TECHNOLOGY CO., LTD, New Taipei (TW)

(21) Appl. No.: 13/650,522

(22) Filed: Oct. 12, 2012

Related U.S. Application Data
(60) Provisional application No. 61/547,269, filed on Oct. 14, 2011.

(51) Int. Cl. H05K 7/10

(52) U.S. Cl. 361/735

(57) ABSTRACT

An electronic device assembly includes at least two electronic devices. Each electronic device has a body, two circuit boards and a flexible circuit board. A male connector and a female connector are installed at the positions corresponding to two ends of the body respectively, and the male and female connectors matching with each other in terms of specification. The two circuit boards are disposed at the two ends of the body respectively, and the two circuit boards are located between the male and female connectors and connected to the male and female connectors respectively. The two circuit boards are connected through the flexible circuit board to electrically connect the male and female connectors, in which the male connector of one electronic device and the female connector of the other electronic device are joined.

### CROSS-REFERENCE TO RELATED APPLICATIONS

This application claims priority to and the benefit of, pursuant to 35 U.S.C. §119(e), U.S. provisional patent application Ser. No. 61/547,269, filed Oct. 14, 2011, entitled “Docking Member,” by Wei Zen Lo, the disclosure of which is incorporated herein in its entirety by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates generally to an electronic device with a tandem connection function and an electronic device assembly thereof, and more particularly to an electronic device assembly capable of meeting thickness design requirements of different electronic devices through flexible circuit boards disposed inside electronic devices and implementing a multifunctional tandem connection.

### BACKGROUND OF THE INVENTION

In order to expand multifunctional applications, multiple expansion interfaces having multiple levels of performance are usually disposed on an electronic device for connecting other apparatuses. For example, an SCSI, an SATA, a USB, FireWire, a PCI Express and the like are disposed on a computer so that apparatuses must be connected through external connection cables of different specifications, causing complex structures among apparatuses.

In order to solve the problem, in recent years, Intel developed a thunderbolt technology, and by cooperating with Apple, proposed a computer using the thunderbolt technology. The thunderbolt technology is mainly used for connecting a PC with other apparatuses, in which two present mature technologies, namely, the PCI Express data transmission technology and the DisplayPort display technology are combined. Two channels can transmit the data using the two protocols at the same time, and each channel provides a bidirectional 10-Gbps bandwidth.

However, as multiple thunderbolt connectors disposed on an electronic device are socket connectors, and these socket connectors are located at the same side of the electronic device, making the two electronic devices can only be connected through a transmission cable with a thunderbolt plug connector at both ends, so that multiple electronic devices cannot be directly connected in series through thunderbolt connectors.

Therefore, a heretofore unaddressed need exists in the art to address the aforementioned deficiencies and inadequacies.

### SUMMARY OF THE INVENTION

In one aspect, the present invention is directed to an electronic device with a tandem connection function and an electronic device assembly thereof that is capable of meeting thickness design requirements of different electronic devices through flexible circuit boards disposed inside electronic devices and capable of being directly joined to other external electronic devices to implement a multifunctional tandem connection.

In one embodiment, an electronic device with a tandem connection function according to the present invention includes a body, two circuit boards and a flexible circuit board. The body is installed with a male connector and a female connector at corresponding positions at two ends of the body, respectively. Specifications of the male and female connectors match with each other. The two circuit boards are disposed at two ends of the body, respectively, and the two circuit boards are located between the male and female connectors and connected to the male and female connectors, respectively. The two circuit boards are connected through the flexible circuit board to electrically connect the male and female connectors.

Further, the male connector is disposed with a power plug and a signal plug, and the female connector is disposed with a power socket and a signal socket. The signal plug and the signal socket match with each other, and the power plug and the power socket match with each other, so that the electronic devices of various functions obtain power and work normally.

Furthermore, the signal plug uses the thunderbolt specification, and the electronic devices of various functions can be directly joined, enabling mutual data or video transmission.

Furthermore, the flexible circuit board is for signal transmission, and at least one power cable is disposed between the two circuit boards to electrically connect the two circuit boards to provide high power for the operation of the internal system of the electronic device.

Furthermore, one end of the flexible circuit board and the circuit board are made into an integral structure through one same process, and the other end of the flexible circuit board is electrically connected to the other circuit board through a connector.

Furthermore, a receiving space is provided inside the body. An opening is provided at each of the two ends of the body with the openings being through the body. The two openings connect the receiving space. The two circuit boards are received inside the receiving space and fixedly disposed at the body. The male and female connectors are disposed through the two openings and at least partially exposed from the body respectively, so as to facilitate a tandem stack of the electronic devices.

Furthermore, a flange extending outward is provided at the peripheries of the bottom of the male and female connectors respectively, and the flange is limited between the circuit board and the corresponding body near the circuit board, so that the male and female connectors are fixed at the body and exert the function of position limit protection for the two circuit boards.

Furthermore, at least one circuit board has a thunderbolt conversion processing function module.

In another embodiment, an electronic device assembly includes at least two electronic devices. Each electronic device has a body. One end of the body is installed with a female connector. The female connector is connected to a first circuit board located inside the body. The first circuit board is connected upward to a second circuit board through a flexible circuit board. A male connector is installed at a corresponding position at the other end of the body and connected to the second circuit board. The male and female connectors of the at least two electronic devices match with each other in terms of specification, in which the male connector of one electronic device is joined to the female connector of the other electronic device.

Further, the male connector is disposed with a power plug and a signal plug, and the female connector is disposed with a power socket and a signal socket. The signal plug and the signal socket match with each other, and the power plug and the power socket match with each other, so that the electronic devices of various functions obtain power and work normally.

Furthermore, the signal plug uses the thunderbolt specification, and the electronic devices of various functions are directly joined, so as to enable data or video transmission.

Furthermore, the flexible circuit board is for signal transmission, and the first circuit board is electrically connected to the second circuit board through at least one power cable to provide high power for the operation of the internal system of the electronic device.

Furthermore, at least one of the first circuit board and the second circuit board has a thunderbolt conversion processing function module.

Furthermore, the body has a receiving space. An opening is provided at each of the two ends of the body, with the openings being through the body. The two openings connect the receiving space. The first circuit board and the second circuit board are received inside the receiving space and fixedly disposed at the body. The male and female connectors are disposed through the two openings and at least partially exposed from the body respectively, so as to facilitate a tandem stack among the electronic devices.

Furthermore, the two electronic devices are tandemly connected with a maximum joint overlapped area, and the male and female connectors are located at one same vertical line, so that a small space is occupied with a tandem stack of the multiple electronic devices of various functions.

Compared with the related art, among other things, in an electronic device with a tandem connection function according to the present invention, a male connector and a female connector matching with each other are disposed, so that multiple electronic devices having different functions are directly joined two by two through the male and female connectors without having to further connecting each electronic device, which not only implements multifunctional applications but also saves the space occupied by connecting cables, thereby lowering the cost. In addition, the two circuit boards are connected through a flexible circuit board. Due to the flexibility of the flexible circuit board, different distances may be designed between two circuit boards according to demands to meet different thickness requirements of electronic devices.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a schematic exploded view of an electronic device with a tandem connection function according to one embodiment of the present invention;

FIG. 2 is a schematic view of FIG. 1 after assembly;

FIG. 3 is a schematic exploded view of an electronic device assembly according to one embodiment of the present invention;

FIG. 4 is a schematic view of FIG. 3 after assembly; and

FIG. 5 is a schematic front view of FIG. 4.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

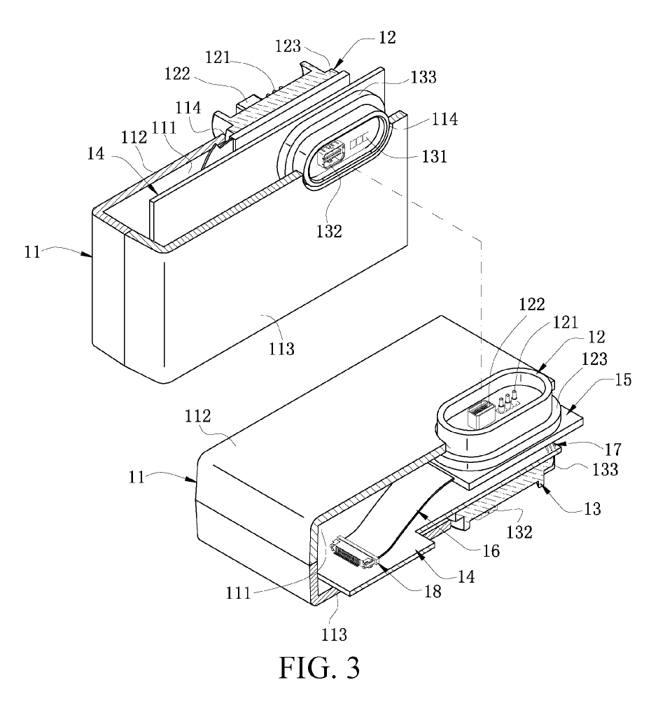

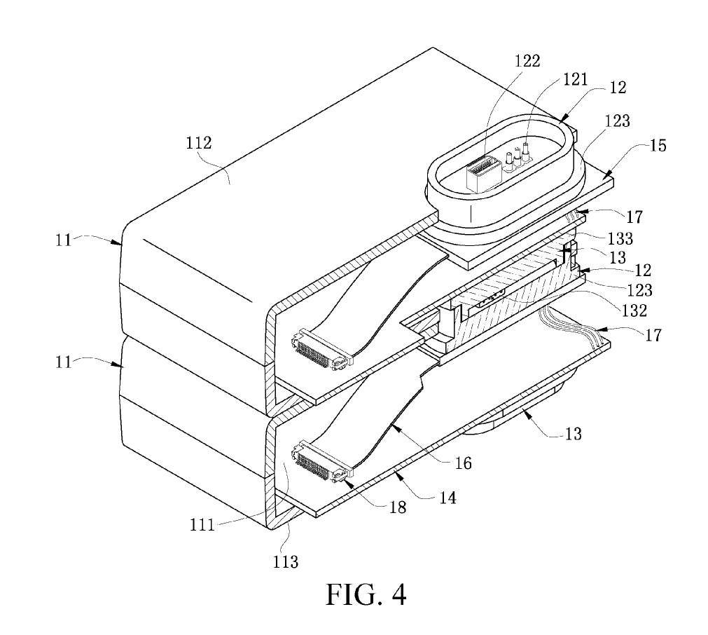

FIGS. 3 and 4 show an electronic device with a tandem connection function and an electronic device assembly thereof according to one embodiment of the present invention. In this embodiment, the electronic device assembly includes two electronic devices 1 both with a tandem connection function. Each electronic device 1 includes a body 11 disposed with a male connector 12 and a female connector 13, two circuit boards, namely, a first circuit board 14 and a second circuit board 15, and a flexible circuit board 16 that connects the first circuit board 14 and the second circuit board 15.

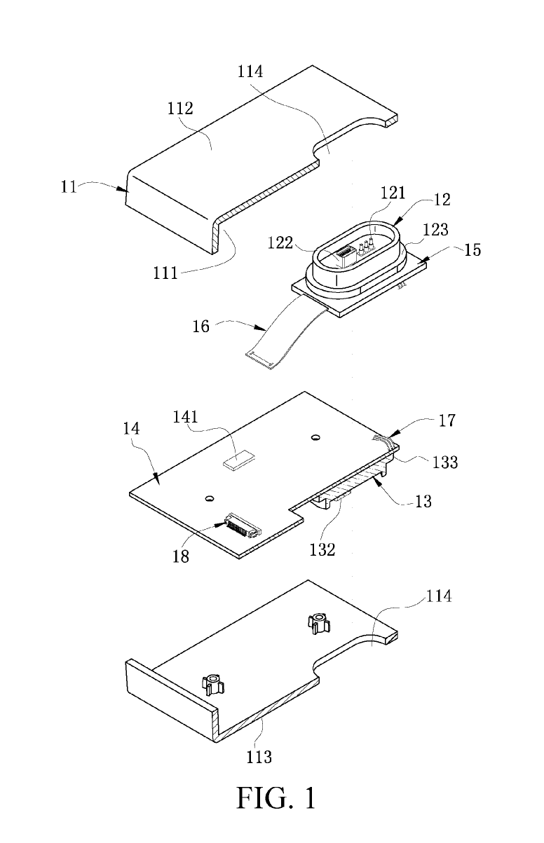

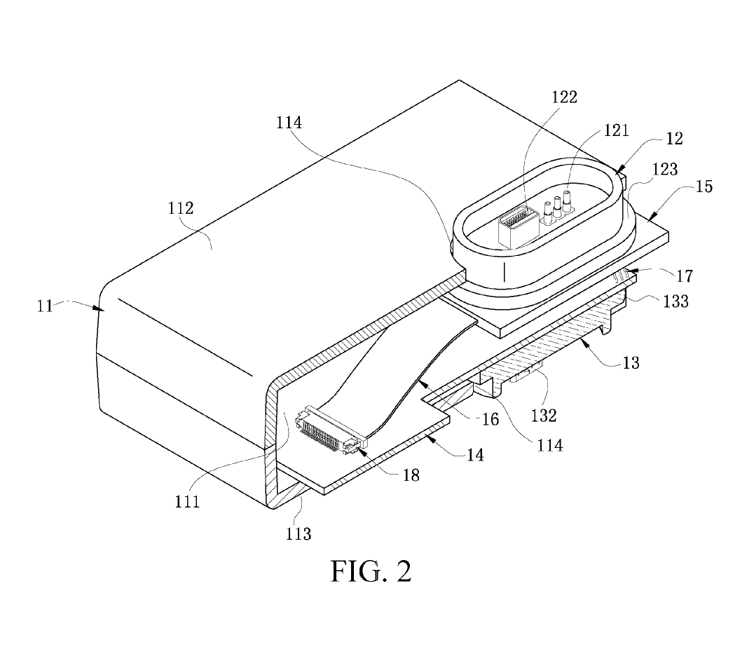

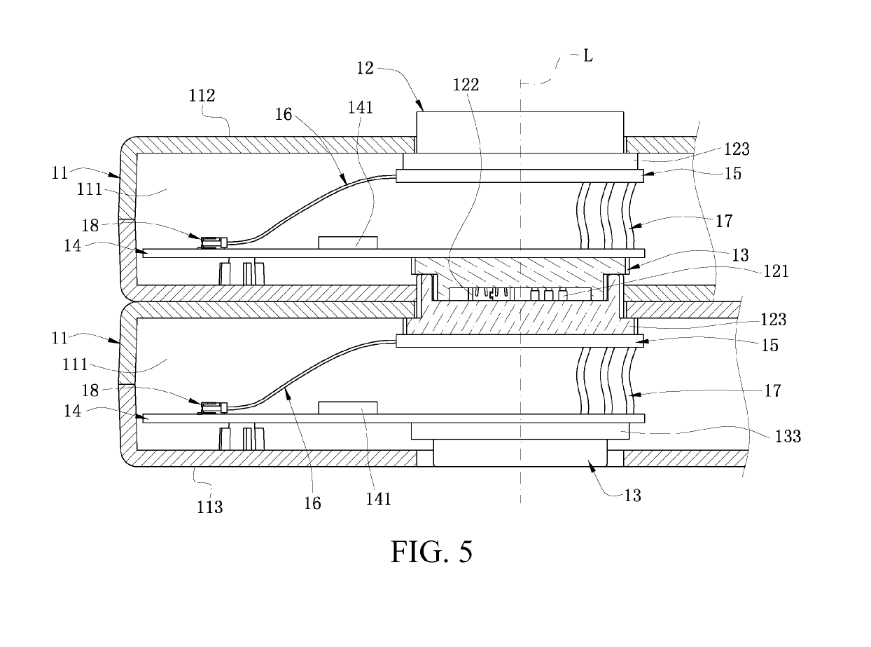

Referring now to FIGS. 1 and 2, the body 11 is approximately a cuboid. The body 11 has a receiving space 111, and an upper end 112 and a lower end 113 disposed opposite to each other and located at the top and the bottom of the receiving space 111. An opening 114 is provided at corresponding positions at each of the upper end 112 and the lower end 113 of the body 11 respectively, with the two openings 114 being through the body 11, namely, the centers of the two openings 114 are located at one same vertical line L (referring to FIG. 5), and the two openings 114 both connect the receiving space 111.

Referring to FIGS. 1 and 2, the upper end 112 is installed with the male connector 12, and the lower end 113 is installed with the female connector 13. The male connector 12 and the female connector 13 match with each other in terms of specification. The male connector 12 and the female connector 13 are disposed through the two openings 114 and at least partially exposed from the body 11 respectively, so that the centers of the male connector 12 and the female connector 13 are also both located at the vertical line L (referring to FIG. 5). The male connector 12 is disposed with a power plug 121 and a signal plug 122, and the female connector 13 is disposed with a power socket 131 and a signal socket 132. The signal plug 122 uses the thunderbolt specification, and the signal socket 132 and the signal plug 122 can be used in combination. The power plug 121 and the power socket 131 also match with each other and can be used in combination. A first flange 123 extending outward is provided at the periphery of the bottom of the male connector 12 which is received in the receiving space 111. A second flange 133 extending outward horizontally is also provided at the periphery of the bottom of the female connector 13 which is received in the receiving space 111.

Referring to FIG. 5, the first circuit board 14 and the second circuit board 15 are both located inside the body 11, i.e., received inside the receiving space 111. The first circuit board 14 and the second circuit board 15 are fixedly disposed on the body 11 through a fixing structure (not shown) respectively, and both the first circuit board 14 and the second circuit board 15 is kept at a certain distance from the corresponding body 11. Meanwhile, the first circuit board 14 and the second circuit board 15 are both located between the male connector 12 and the female connector 13. The female connector 13 and the first circuit board 14 near the lower end 113 are connected vertically. At this time, the second flange 133 is limited between the lower end 113 and the first circuit board 14. The male connector 12 and the second circuit board 15 near the upper end 112 are connected vertically, and the first flange 123 is limited between the upper end 112 and the second circuit board 15. The first flange 123 and the second flange 133 are disposed to fix the male connector 12 and the female connector 13 at the body 11, and exert the function of position limit protection for the first circuit board 14 and the second circuit board 15.

Referring to FIGS. 1 and 5, in this embodiment, the first circuit board 14 is disposed with a processing module 141, and the electronic device 1 performs conversion processing on a data or video signal transmitted by the electronic device 1 with the processing module 141 to meet the thunderbolt transmission specification. In other embodiments, the processing module 141 may be disposed on the second circuit board 15.

Referring to FIGS. 1 and 5, the first circuit board 14 is connected upward to the second circuit board 15 through the flexible circuit board 16, and the flexible circuit board 16 is for signal transmission and does not transmit power. As the electronic device 1 performs conversion processing on a data or video signal transmitted by the electronic device 1 with the processing module 141 to meet the thunderbolt transmission specification for transmission, high power is required to complete data reconstruction. Therefore, three power cables 17 may be disposed between the first circuit board 14 and the second circuit board 15 for connection and providing high power. In other embodiments, one power cable 17 may be used.

In this embodiment, the flexible circuit board 16 and the second circuit board 15 may be made into an integral structure during the production process. The trace contact at one end of the flexible circuit board 16 may be connected to an output contact of the transmission trace of the second circuit board 15 through process production, and the other end of the flexible circuit board 16 is electrically connected to the first circuit board 14 through an electrical connector 18. Due to the flexibility of the flexible circuit board 16, according to the demands, the flexible circuit board 16 may be bent inside the receiving space 111, or different distances between the first circuit board 14 and the second circuit board 15 may also be adjusted to meet different thickness requirements of the electronic device 1.

Referring to FIGS. 4 and 5, the male connector 12 of one electronic device 1 and the female connector 13 of the other the electronic device 1 are joined to form an electronic device assembly. At this time, the signal plug 122 and the signal socket 132 of the thunderbolt specification are matched and connected, the power plug 121 and the power socket 131 are matched and connected, and the two electronic devices 1 are joined through the power plug 121 and the power socket 131, thereby implementing the power supply for the operation thereof. The two electronic devices 1 are tandemly stacked with a maximum joint overlapped area, in which the centers of the male connector 12 and the female connector 13 are also located at the vertical line L. Therefore, the properly arranged two electronic devices 1 are tandemly stacked and occupy a small space. Alternatively, the two electronic devices 1 may have different functions. That is, the electronic devices 1 have the same structure but have different functions.

Alternatively, when the electronic device assembly includes three and more electronic devices 1 with a tandem connection function, a next electronic device 1 is tandemly stacked through the male connector 12 (or the female connector 13) disposed thereon and the female connector 13 (or the male connector 12) on a previous electronic device 1. The power supply required for the operation thereof is implemented through the power plug 121 and the power socket 131 on each of the electronic devices 1. The multiple electronic devices 1 are all tandemly stacked with a maximum joint overlapped area, in which the centers of the male connector 12 and the female connector 13 are also located at the vertical line L, so that the multiple electronic devices 1 of various functions are tandemly stacked and occupy a small space.

In conclusion, among other things, the electronic device with a tandem connection function and the electronic device assembly thereof according to the present invention has the following advantages:

1. As the electronic device 1 is disposed with a male connector 12 and a female connector 13 matching with each other, and the signal plug 122 uses thunderbolt specification, multiple electronic devices 1 of different functions are directly joined two by two through one male connector 12 and one female connector 13 without having to further disposing connecting cables to connect the electronic devices 1, so that not only multifunctional applications are implemented, and the space occupied by connecting cables is saved, thereby lowering the cost.

2. As the electronic device 1 is disposed with a power plug 121 and a power socket 131, the electronic devices are joined two by two through one power plug 121 and one power socket 131, thereby implementing the power supply required for the operation thereof.

3. Due to the flexibility of the flexible circuit board 16, according to the demands, the flexible circuit board 16 may be bent inside the receiving space 111, or different distances between the first circuit board 14 and the second circuit board 15 may also be adjusted to meet different thickness requirements of the electronic device 1.

4. As the flexible circuit board 16 is for signal transmission and does not transmit power, and the electronic device 1 performs conversion processing on data or video information of the electronic device with the processing module 141 to meet the thunderbolt transmission specification for transmission, high power is required to complete data construction. Therefore, power cables 17 are disposed between the first circuit board 14 and the second circuit board 15 for connection and for providing high power.

5. The male connector 12 and the female connector 13 are disposed through the two openings 114 and at least partially exposed from the body 11 respectively, so as to facilitate a tandem stack of the electronic devices 1.

6. The first flange 123 is limited between the upper end 112 and the second circuit board 15, and the second flange 133 is limited between the lower end 113 and the first circuit board 14, so that the male connector 12 and the female connector 13 are fixed at the body 11, and exerts the function of position limit protection for the first circuit board 14 and the second circuit board 15.

7. Multiple electronic devices 1 are tandemly stacked with a maximum joint overlapped area, and the male connector 12 and the female connector 13 are located at the vertical line L, so that the multiple electronic devices 1 of various functions are tandemly stacked and occupy a small space.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electronic device with a tandem connection function, comprising:
a body, installed with a male connector and a female connector at corresponding positions at two ends of the body respectively, and the male and female connectors matching with each other in terms of specification;
two circuit boards, disposed at the two ends of the body respectively, and the two circuit boards being located between the male and female connectors and being connected to the male and female connectors respectively; and
a flexible circuit board, the two circuit boards being connected through the flexible circuit board to electrically connect the male and female connectors.

2. The electronic device according to claim 1, wherein the male connector is disposed with a power plug and a signal plug, the female connector is disposed with a power socket and a signal socket, the signal plug and the signal socket match with each other, and the power plug and the power socket match with each other.

3. The electronic device according to claim 2, wherein the signal plug uses the thunderbolt specification.

4. The electronic device according to claim 3, wherein at least one circuit board has a thunderbolt conversion processing function module.

5. The electronic device according to claim 1, wherein the flexible circuit board is for signal transmission, and at least one power cable is disposed between the two circuit boards to electrically connect the two circuit boards.

6. The electronic device according to claim 1, wherein one end of the flexible circuit board and one circuit board are integrally formed, and the other end of the flexible circuit board is electrically connected to the other circuit board through a connector.

7. The electronic device according to claim 1, wherein a receiving space is provided inside the body, an opening is provided at each of two ends of the body respectively with the openings being through the body, the two openings connect the receiving space, the two circuit boards are received inside the receiving space and fixedly disposed at the body, the male and female connectors are disposed through the two openings and at least partially exposed from the body respectively.

8. The electronic device according to claim 1, wherein a flange extending outward is provided at the peripheries of the bottoms of the male and female connectors respectively, and the flange is limited between the circuit board and the corresponding body near the circuit board.

9. An electronic device assembly, comprising:
at least two electronic devices, each electronic device having a body, one end of the body being installed with a female connector, the female connector being connected to a first circuit board located inside the body, the first circuit board being connected upward to a second circuit board through a flexible circuit board, a male connector being installed at the position corresponding to the other end of the body and being connected to the second circuit board, the male and female connectors of the at least two electronic devices matching with each other in terms of specification, wherein the male connector of one electronic device and the female connector of the other electronic device are joined.

10. The electronic device assembly according to claim 9, wherein the male connector is disposed with a power plug and a signal plug, the female connector is disposed with a power socket and a signal socket, the signal plug and the signal socket match with each other, and the power plug and the power socket match with each other.

11. The electronic device assembly according to claim 10, wherein the signal plug uses thunderbolt specification.

12. The electronic device assembly according to claim 11, wherein at least one of the first circuit board and the second circuit board has a thunderbolt conversion processing function module.

13. The electronic device assembly according to claim 9, wherein the flexible circuit board is for signal transmission, and the first circuit board is electrically connected to the second circuit board through at least one power cable.

14. The electronic device assembly according to claim 9, wherein a receiving space is provided inside the body, an opening is provided at each of two ends of the body respectively with the openings being through the body, the two openings connect the receiving space, the first circuit board and the second circuit board are received inside the receiving space and fixedly disposed at the body, and the male and female connectors are disposed inside the two openings and at least partially exposed from the body respectively.

15. The electronic device assembly according to claim 9, wherein the two electronic devices are tandemly connected with a maximum joint overlapped area, and the male and female connectors are located at one same vertical line.
